(19) United States
(12) Patent Application Publication
(10) Pub. No.: US 2009/0225519 A1
(43) Pub. Date: Sep. 10, 2009

(54) MEDICINE CABINET ASSEMBLY

(75) Inventors: James V. Mischel, JR., Seattle, WA (US); James V. Mischel, SR., Lynnwood, WA (US); Patrick Daniel Erickson, Seattle, WA (US)

Correspondence Address: PELOQUIN, PLLC, 800 FIFTH AVENUE, SUITE 4100, SEATTLE, WA, 98104-3100, US

(73) Assignee: Electric Mirror, LLC, Everett, WA (US)

(21) Appl. No.: 12/383,624

(22) Filed: Mar. 27, 2009

Related U.S. Application Data
(63) Continuation-in-part of application No. 11/563,119, filed on Nov. 24, 2006.
(60) Provisional application No. 60/794,209, filed on Apr. 21, 2006.
(60) Provisional application No. 60/739,399, filed on Nov. 23, 2005.
(60) Provisional application No. 60/739,156, filed on Nov. 23, 2005.
(60) Provisional application No. 61/040,586, filed on Mar. 28, 2008.

(51) Int. Cl. H05K 5/00; H04N 5/50

(52) U.S. Cl. 361/724; 348/731

(57) ABSTRACT

An apparatus includes a first mirror platform; the first mirror platform has a first portion and a second portion. A media display device is disposed behind the first mirror platform, such that within the second portion information displayed on the media display device is visible when the media display device is on and is viewed from in front of the first mirror platform. A mounting platform is coupled to a back of the first mirror platform to form a door assembly and the mounting platform can also be a mirror platform.

### RELATED APPLICATIONS

This patent application claims priority from commonly assigned U.S. Provisional Patent Application Ser. No. 61/040,586 filed on Mar. 28, 2008,

This patent application is a continuation-in-part of commonly assigned U.S. patent application Ser. No. 11/563,119, filed on Nov. 24, 2006, which claims the benefit of U.S. Provisional Patent Application No. 60/739,156, filed on Nov. 23, 2005; U.S. patent application Ser. No. 11/563,119 claims the benefit of U.S. Provisional Patent Application No. 60/739,399, filed on Nov. 23, 2005; and U.S. patent application Ser. No. 11/563,119 claims the benefit of U.S. Provisional Patent Application No. 60/794,209, filed on Apr. 21, 2006.

U.S. Provisional Patent Application Ser. No. 61/040,586 filed on Mar. 28, 2008, is hereby incorporated by reference into the present application. U.S. patent application Ser. No. 11/563,119, filed on Nov. 24, 2006; U.S. Provisional Patent Application No. 60/739,156, filed Nov. 23, 2005; U.S. Provisional Patent Application No. 60/739,399, filed on Nov. 23, 2005; and U.S. Provisional Patent Application No. 60/794,209, filed on Apr. 21, 2006 are hereby incorporated by reference into the present application.

### BACKGROUND OF THE INVENTION

1. Field of Invention

The invention relates generally to medicine cabinet assemblies, and more specifically to lighting and media display systems.

2. Art Background

In today's fast-paced world, people often have a television in their bathroom so that they may watch the news or other television shows while they are getting ready in the morning, cleaning up at night, etc. Currently available mirror and television devices typically include a television mounted to the back of a mirror. This arrangement is a convenient, space-saving device, as it embeds a television in the existing space occupied by a mirror. Although the mirror/television assembly conserves space in most bathrooms, very small bathrooms often require a mirrored medicine cabinet for extra storage space. Thus, a television cannot be secured behind the mirror without interfering with the storage area in the medicine cabinet. This may present a problem. Moreover, if the ceiling in a bathroom is low, the medicine cabinet must often be decreased in size to allow for a suitable light fixture to be secured above the medicine cabinet. This may present a problem.

### BRIEF DESCRIPTION OF THE DRAWINGS

The invention may best be understood by referring to the following description and accompanying drawings that are used to illustrate embodiments of the invention. The invention is illustrated by way of example in the embodiments and is not limited in the figures of the accompanying drawings, in which like references indicate similar elements.

FIG. 1 is an isometric view of a medicine cabinet assembly constructed in accordance with one embodiment of the present disclosure.

FIG. 2 is an exploded view of the medicine cabinet of FIG. 1.

FIG. 3 illustrates a block diagram of a media display device.

### DETAILED DESCRIPTION

In the following detailed description of embodiments of the invention, reference is made to the accompanying drawings in which like references indicate similar elements, and in which is shown by way of illustration, specific embodiments in which the invention may be practiced. These embodiments are described in sufficient detail to enable those of skill in the art to practice the invention. In other instances, well-known circuits, structures, and techniques have not been shown in detail in order not to obscure the understanding of this description. The following detailed description is, therefore, not to be taken in a limiting sense, and the scope of the invention is defined only by the appended claims.

Apparatuses and methods are described, which provide an integration of lighting and media display within a part of a medicine cabinet. Within this description of embodiments, the terms “invention” and “present invention” are synonymous with “present disclosure.”

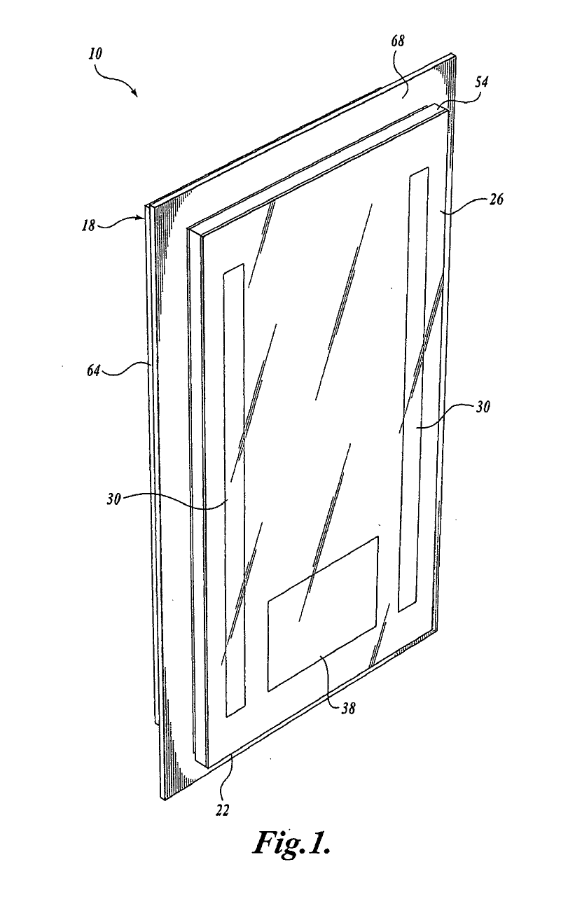

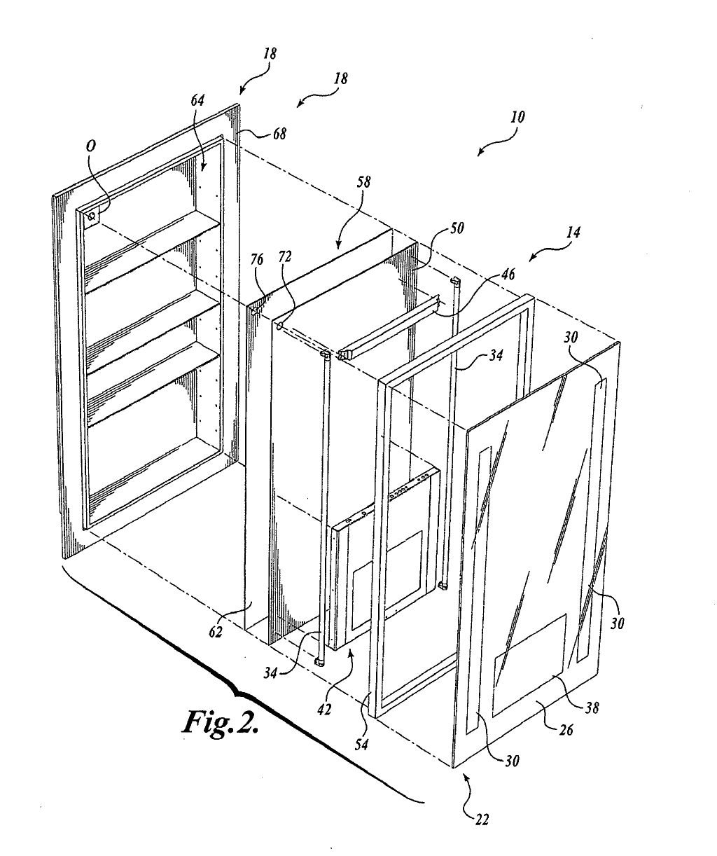

A medicine cabinet assembly 10, constructed in accordance with one embodiment of the present disclosure, is best understood by referring to FIGS. 1 and 2. The medicine cabinet assembly 10 includes a door assembly 14 hingedly connected to a cabinet 18. The door assembly 14 includes a framed or frameless first mirror platform 22 having a first substantially reflective surface 26 on a first side of the mirror platform 22 and a first non-reflective surface (not shown) on a second side of the mirror platform 22. It will be noted by those of skill in the art that the first mirror platform 22, as described herein, is made with a layer of glass and that a first substantially reflective surface 26 can be applied to either side of the layer of glass.

The first mirror platform 22 further includes one or more translucent backlit portions 30 that have substantially no reflectivity (e.g., frosted glass, acid etched glass, or clear glass). The backlit portions 30 are translucent, allowing light emitted from one or more light sources 34 disposed within the door assembly 14 to pass through the first mirror platform 22. The number, configuration, and arrangement of backlit portions 30 can be varied to achieve different lighting effects. As a non-limiting example, the backlit portion 30 may be configured as two parallel, substantially straight portions formed along each side of the first mirror platform 22 or, instead, as a single, continuous portion extending around the perimeter of the first mirror platform 22.

The first mirror platform 22 further includes a media display device viewing portion 38 through which a media display device 42 located behind the first mirror platform 22 can be viewed. The media display device viewing portion 38 is both reflective and transmissive. Any suitable mirror technology may be used to allow the media display device viewing portion 38 to operate at maximum reflectivity when the media display device 42 is turned off, and to allow light from the media display device 42 to be transmitted therethrough when the media display device 42 is turned on. More specifically, the reflectivity of the media display device viewing portion 38 closely matches the rest of the first reflective surface 26 when the media display device 42 is turned off, causing the media display device viewing portion 38 to blend in with the rest of the first reflective surface 26. However, the user can view the images on the media display device 42 when the media display device 42 is turned on. In another embodiment, the media display device viewing portion 38 blends with the first reflective surface 26, and appears black when the media display device is turned off. In another embodiment, the media display device viewing portion 38 blends with the first reflective surface 26 rendering the media display device viewing portion 38 partially reflective when the media display device is turned off.

The media display device 42, light sources 34, and any other electrical components, such as an electrical ballast 46, are positioned behind the first mirror platform 22 and secured to a mounting platform 50 substantially identical in shape and size to the first mirror platform 22. Alternatively, the electrical ballast 46 can be located in or behind the cabinet 18. The mounting platform 50 is formed from a suitable material, such as wood, metal, plastic, etc. to allow the electrical components to be mounted directly thereto. Preferably, each light source 34 is mounted to the mounting platform 50 such that it is positioned directly behind each translucent backlit portion 30. Alternatively, the light sources 34 can be mounted such that they are offset from portion 30; thus, in such an embodiment, the light sources 34 are not directly behind portion 30. Moreover, the media display device 42 is positioned on the mounting platform 50 such that the screen of the media display device 42 aligns with the media display device viewing portion 38 of the first mirror platform 22. In one embodiment, the mounting platform 50 can be a mirror platform itself or include a mirror platform, thereby providing a mirrored surface on either side of the door assembly 14.

Any suitable electrical components may be used. For instance, the light source 34 may be a fluorescent lamp, a light-emitting diode (LED) strip assembly, light emitting film, etc. Moreover, a media display device 42 may be any media display device suitable for receiving television signals, computer signals, VGA connections, digital signals, etc., and displaying a corresponding image. In various embodiments, the media display device can be constructed using a liquid crystal display (LCD), an organic light emitting diode (OLED), or other flat display technology. In one embodiment a media display device 42 is located within a door assembly 14. In another embodiment, a display screen of a media display device is located within the door assembly 14 behind the first mirror platform 22 and the rest of the media display electronics, such as for example, TV tuner, power supply, etc., are separate from the display screen and are located within the interior chassis 54 of the door assembly 14. In yet another embodiment, a display screen of a media display device is located within the door assembly 14, and the rest of the media display electronics, such as for example, TV tuner, power supply, etc., are outside of the door assembly 14, located in or behind the cabinet 18.

In one embodiment, to form a portion of the door assembly 14, the first mirror platform 22 and mounting platform 50 are each secured to opposite sides of an interior chassis or frame 54 with the first reflective surface 26 of the first mirror platform 22 facing away from the chassis 54. Preferably, interior chassis or frame 54 is substantially identical in shape and size to both the first mirror platform 22 and the mounting platform 50 such that the exterior edges of the interior chassis 54, the first mirror platform 22, and the mounting platform 50 are substantially flush with each other. The interior chassis 54 includes a substantially large opening to house the electrical components disposed between the mounting platform 50 and the first mirror platform 22. The first mirror platform 22 and the mounting platform 50 are secured to the interior chassis 54 in any suitable manner, such as with fasteners or with an adhesive. In another embodiment, the mounting platform 50 provides the functionality of the interior chassis 54; thereby eliminating the need for a separate interior chassis.

In one embodiment, to complete the door assembly 14, a second mirror platform 58 is secured to the back side of the mounting platform 50 opposite the electrical components. The second mirror platform 58 includes a second reflective surface (not shown) formed on one side of the second mirror platform 58 and a second non-reflective surface 62 formed on the opposite side of the second mirror platform 58. The second mirror platform 58 is secured to the back side of the mounting platform 50 with the second non-reflective surface 62 adjacent to the back side of the mounting platform 50. Note that the second reflective surface can be formed on either side of the second mirror platform 58.

The door assembly 14 is hingedly connected to the cabinet 18 in any suitable manner well known in the art, allowing the door assembly 14 to be moved between open and closed positions. For instance, piano hinges, scissor-style hinges, or any other suitable hinges (not shown) may be used. The door assembly 14 includes a first reflective surface 26 on the front of the door assembly 14 and a second reflective surface formed on the back of the door assembly 14. Thus, a reflective surface is provided for the user when the door assembly 14 is in either the open or closed position.

The cabinet 18 may be of any suitable design well known in the art, such as a surface mount cabinet or a recessed cabinet. The cabinet 18 preferably includes a storage portion 64 having a plurality of shelves disposed therein for storing items thereon such as medicine bottles, toiletries, hair products, etc. The cabinet 18 may further include a frame 68 disposed around the exterior of the storage portion 64. In one embodiment, the frame 68 may be substantially similar in shape to the door assembly 14 yet larger in size such that the frame 68 is visible behind the door assembly 14 when the door assembly 14 is in the closed position. In another embodiment, the frame 68 is not visible behind the door assembly 14 when the door assembly 14 is in the closed position.

Preferably, the storage portion 64 includes an opening sized to receive an electrical outlet O therein. Moreover, the mounting platform 50 and the second mirror platform 58 preferably include first and second aligned openings 72 and 76 that define an electrical passageway for routing electrical cabling and wiring of the electrical components therethrough. Preferably, first and second openings 72 and 76 are positioned on the mounting platform 50 and the second mirror platform 58 such that are substantially aligned with the opening defined in the storage portion 64 for the electrical outlet O. As such, the electrical components of the medicine cabinet assembly 10 may be easily placed into communication with the electrical outlet O. Moreover, the first and second openings 72 and 76 are preferably formed near the edges of the mounting platform 50 and second mirror platform 58 adjacent the hinge (not shown) of the door assembly 14 such that the electrical cabling and wiring does not interfere with the opening of the door assembly 14.

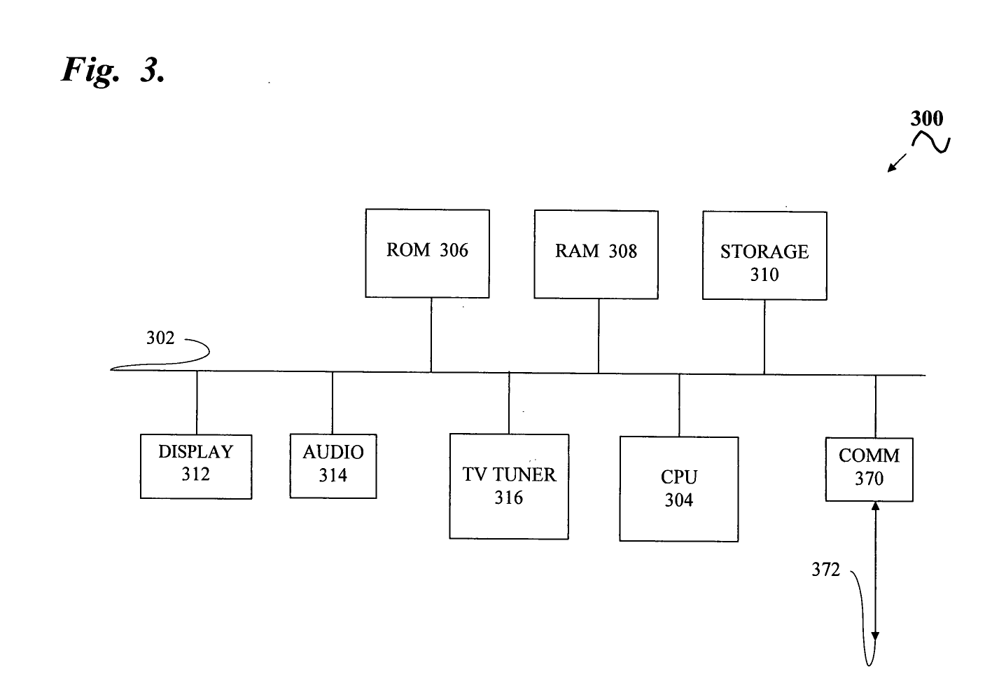

FIG. 3 illustrates, generally at 300, a block diagram of a media display device in which computer signals can be displayed according to various embodiments of the invention. The block diagram is a high-level conceptual representation and may be implemented in a variety of ways and by various architectures. With reference to FIG. 3, a bus system 302 interconnects a Central Processing Unit (CPU) 304, Read Only Memory (ROM) 306, Random Access Memory (RAM) 308, storage 310, display 312, audio 314, television (TV) tuner 316, and communications 370. In various embodiments, the display 312 can be configured as a touch screen or a non-touch screen. The bus system 302 may be for example, one or more of such buses as a system bus, Peripheral Component Interconnect (PCI), Advanced Graphics Port (AGP), Small Computer System Interface (SCSI), Institute of Electrical and Electronics Engineers (IEEE) standard number 1394 (FireWire), Universal Serial Bus (USB), or a dedicated bus designed for a custom application, etc. The CPU 304 may be a single, multiple, or even a distributed computing resource. Storage 310 may be Compact Disc (CD), Digital Versatile Disk (DVD), hard disks (HD), optical disks, tape, flash, memory sticks, video recorders, etc. Note that depending upon the actual implementation of a media display device, the media display device may include some, all, more, or a rearrangement of components in the block diagram.

Connection with a network, such as an intranet or the Internet is obtained via 372 and communication 370, as is recognized by those of skill in the art, which enables the media display device 300 to communicate with other data processing devices in remote locations as well as to receive and display television broadcasts with the TV tuner 316. Communication 370 can provide wireless connectivity utilizing protocols such as IEEE 802.11b, 802.11a, 802.11g, 802.11n as well as protocols not yet developed. Alternatively, communications 370 can provide a hardwire connection.

The media display device 300 can be configured as a desktop computer, work station, or with a remote slim profile form factor for mounting in or behind a medicine cabinet. The media display device 300 can be configured to run for example a WINDOWS® compatible operating systems such as WINDOWS® XP Home or WINDOWS® XP, WINDOWS® XP Professional, WINDOWS® VISTA Professional Linux, etc. or the media display device 300 can be implemented with a computer from APPLE COMPUTER, Inc. running operating systems such as OS X, etc.

In certain applications where it is desired to minimize volume, a display 312 can be mounted in a door assembly of a cabinet (such as in the door assembly 14 of the cabinet 18 in FIG. 2) and the rest of components shown in FIG. 3 can be mounted in or behind the cabinet 18 (FIG. 2). Audio 314 can be included in a door assembly or it can be incorporated into a cabinet, such as cabinet 18 (FIG. 2). Audio 18 is used to provide sound to the user of the media display device 300.

For purposes of discussing and understanding the embodiments of the invention, it is to be understood that various terms are used by those knowledgeable in the art to describe techniques and approaches. Furthermore, in the description, for purposes of explanation, numerous specific details are set forth in order to provide a thorough understanding of the embodiments. It will be evident, however, to one of ordinary skill in the art that the embodiments may be practiced without these specific details. In some instances, well-known structures and devices are shown in block diagram form, rather than in detail, in order to avoid obscuring the embodiments. These embodiments are described in sufficient detail to enable those of ordinary skill in the art to practice the invention, and it is to be understood that other embodiments may be utilized and that logical, mechanical, electrical, and other changes may be made without departing from the scope of the present invention.

As used in this description, “one embodiment” or “an embodiment” or similar phrases means that the feature(s) being described are included in at least one embodiment of the invention. References to “one embodiment” in this description do not necessarily refer to the same embodiment; however, neither are such embodiments mutually exclusive. Nor does “one embodiment” imply that there is but a single embodiment of the invention. For example, a feature, structure, act, etc. described in “one embodiment” may also be included in other embodiments. Thus, the invention may include a variety of combinations and/or integrations of the embodiments described herein.

While the invention has been described in terms of several embodiments, those of skill in the art will recognize that the invention is not limited to the embodiments described, but can be practiced with modification and alteration within the spirit and scope of the appended claims. The description is thus to be regarded as illustrative instead of limiting.

What is claimed is:

1. An apparatus comprising:
a first mirror platform, the first mirror platform having a first portion and a second portion;
a media display device, the media display device is disposed behind the first mirror platform, such that within the second portion information displayed on the media display device is visible when the media display device is on and is viewed from in front of the first mirror platform; and
a mounting platform, the mounting platform is coupled to a back of the first mirror platform to form a door assembly.

2. The apparatus of claim 1, further comprising:
a light source, the light source is disposed behind the first mirror platform and light from the light source can pass through a third portion in the first mirror platform to illuminate a user when the user is in front of the first mirror platform.

3. The apparatus of claim 2, wherein the light source is selected from the group consisting of a light emitting diode (LED), a fluorescent lamp, and a light emitting film.

4. The apparatus of claim 1, wherein a display screen of the media display device is separated from the media display device.

5. The apparatus of claim 4, wherein the display screen is mounted within the door assembly and at least a part of the media display device components is located outside of the door assembly.

6. The apparatus of claim 5, wherein a TV tuner is located outside of the door assembly.

7. The apparatus of claim 1, wherein the media display device can receive a signal selected from the group consisting of a television signal, a computer signal, and a digital signal and then display an image using the signal.

8. The apparatus of claim 7, wherein the media display device is connected to a network.

9. The apparatus of claim 1, further comprising:
an electrical ballast, the electrical ballast is mounted outside of the door assembly.

10. The apparatus of claim 1, further comprising:
a cabinet assembly, the cabinet assembly is hingedly coupled to the door assembly.

11. The apparatus of claim 1, the door assembly further comprising:
a second mirror platform, the second mirror platform is coupled to a back of the mounting platform, wherein the door assembly provides a reflection to the user from either a front side or a back side of the door assembly.

12. The apparatus of claim 1, wherein the third portion has a general shape.

13. The apparatus of claim 12, wherein the third portion is further comprised of a first and a second substantially straight portions, wherein the first substantially straight portion extends on a right side of the mirror platform and the second substantially straight portion extends on a left side of the mirror platform.

14. The apparatus of claim 12, wherein the third portion extends around a perimeter of the first mirror platform.

15. The apparatus of claim 1, wherein the third portion has substantially no reflectivity.

16. The apparatus of claim 15, wherein a glass preparation of the third portion is selected from the group consisting of frosted glass, acid etched glass, and clear glass.

17. The apparatus of claim 1, wherein a reflectivity of the second portion closely matches a reflectivity of the first portion when at least a display screen of the media display device is positioned behind the second portion and the media display device is turned off.

18. The apparatus of claim 1, wherein the second portion appears black when the media display device is turned off.

19. The apparatus of claim 1, wherein the second portion is partially reflective when the media display device is turned off.

20. A method comprising:
partitioning a surface area of a first mirror platform into two portions, a first portion and a second portion, the first portion has a first reflectivity and the second portion has a second reflectivity, wherein the first reflectivity is greater than or equal to the second reflectivity; and
enclosing at least a display screen of a media display device between the first mirror platform and a mounting platform to form a door assembly.

21. The method of claim 20, wherein the partitioning further comprises a third portion having a third reflectivity, and the third reflectivity is less than or equal to the second reflectivity.

22. The method of claim 20, wherein the enclosing further comprises a light source, the light source provides a source of light from inside the door assembly, wherein light from the source of light can pass through the third portion and illuminate a user when the user is in front of the first mirror platform.

23. The method of claim 20, further comprising:
combining a second mirror platform to a back side of the mounting platform.

24. The method of claim 20, wherein the mounting platform is a second mirror platform.

25. The method of claim 23, further comprising:
configuring a cabinet assembly to be hingedly coupled with the door assembly.

26. An apparatus comprising:
a first mirror platform, the first mirror platform having a first portion, and a third portion;
a light source, the light source is disposed behind the first mirror platform, light from the light source can pass through the third portion to illuminate a user when the user is in front of the first mirror platform wherein the user's reflection is visible in the first portion; and
a mounting platform, the mounting platform is coupled to a back of the first mirror platform to form a door assembly.

27. The apparatus of claim 26, further comprising:
a media display device, the media display device is disposed behind a second portion of the first mirror platform, such that within the second portion information displayed on the media display device, when the media display device is on, is visible from the front of the first mirror platform.

28. The apparatus of claim 26, wherein the light source is selected from the group consisting of a light emitting diode (LED), a fluorescent lamp, and a light emitting film.

29. The apparatus of claim 26, wherein the third portion is further comprised of a first and a second substantially straight portions, wherein the first substantially straight portion extends along a right side of the first mirror platform and the second substantially straight portion extends along a left side of the first mirror platform.

30. The apparatus of claim 26, wherein the third portion extends around a perimeter of the first mirror platform.

31. The apparatus of claim 26, wherein the third portion has substantially no reflectivity.

32. The apparatus of claim 31, wherein a glass preparation of the third portion is selected from the group consisting of frosted glass, acid etched glass, and clear glass.
